(19) United States
(12) Patent Application Publication
(10) Pub. No.: US 2017/0260619 A1
(43) Pub. Date: Sep. 14, 2017

(54) METHOD FOR PRODUCING NEUTRON CONVERTERS

(71) Applicant: HELMHOLTZ-ZENTRUM GEESTHACHT ZENTRUM FÜR MATERIAL-UND KÜSTENFORSCHUNG GMBH, Geesthacht (DE)

(72) Inventors: Micheal Störmer, Hamburg (DE); Christian Horstmann, Geesthacht (DE); Gregor Nowak, Hamburg (DE); Reinhard Kampmann, Adendorf (DE); John Hedde, Wendisch-Evern (DE)

(21) Appl. No.: 14/900,253

(22) PCT Filed: Jun. 29, 2015
(86) PCT No.: PCT/EP2015/064751

§ 371 Date: Dec. 21, 2015

(30) Foreign Application Priority Data
Jul. 14, 2014 (EP) 14176907.5

(51) Int. Cl. C23C 14/06; C23C 14/34; G01T 3/00; C23C 14/02

(52) U.S. Cl. CPC C23C 14/0635; C23C 14/028; C23C 14/34; G01T 3/00

(57) ABSTRACT

The present invention relates to a method for producing a neutron converter from boron carbide or a boron film on a neutron transparent metal substrate. The neutron transparent metal substrate is polished in a first step by fine grinding and coated in a further step by means of sputtering with boron carbide or a boron film. An adhesion promoting layer is optionally applied between the metal substrate and below the boron or boron carbide layer. The coatings obtained have a high homogeneity in layer thickness, chemical composition and isotope ratio as well as a low level of impurities such as oxygen or nitrogen.

### CROSS REFERENCE TO RELATED APPLICATIONS

This Application is a National Stage of PCT/EP2015/064751 filed Jun. 29, 2015, which claims priority to European Patent Application No. 14176907.5 filed Jul. 14, 2014, the respective discloses of which are each incorporated herein by reference in their entireties.

### FIELD OF THE DISCLOSURE

The present invention relates to a method for producing neutron converters.

### BACKGROUND OF THE INVENTION

Neutrons are used nowadays in basic research and in the characterization of biological and condensed matter. This versatile probe allows, through its internal properties, temporally and spatially resolved studies on single crystals, magnetic layers, polymer membranes, in particular biological cells, by means of diffraction, reflectometry, small-angle scattering, spectroscopy and also tomography. If the kinetic energy of the neutrons is reduced by moderators and selectors to thermal energy, the de Broglie wavelength of the neutrons then corresponds with sufficient precision to the atomic spacing in solids. The structure of a solid can thus be examined very precisely through scattering processes. In low energy regions, neutrons allow conclusions to be drawn concerning internal energy states of the solid. A spatially resolved detection of the neutrons is necessary for this application.

The commonly used detector systems use the gas 3He under high pressure to detect the neutrons. These have a high detection efficiency (up to 95%) with a low counting rate acceptance. 3He counting tubes and so-called multi-wire proportional chamber (MWPC) 3He gas detectors have at best a spatial resolution in the mm range and are used for the production of homogeneous and large-area neutron detectors only with the application of great resources. However, this technology represents the state of the art, as to date there have been no great driving forces to search for alternatives.

Due to the limited availability of 3He and the growing need for neutron detectors, the research into and development of alternative detector materials have been constantly growing in recent times. A known alternative to 3He gas detectors are 10B solid detectors. The isotope 10B has a relatively large neutron absorption cross-section and, associated therewith, an absorption efficiency of 70% in comparison with that of the 3He isotope in a broad energy range of from 10-2 to 104 eV. This corresponds to a waveband from 0.286 nm to 0.286 pm.

The use of 10B solid detectors additionally promises an improvement in the spatial resolution of the neutron detection in comparison with the conventional 3He gas detector. The 10B solid detectors can consist of a base (substrate) or a 10B-containing film.

For realization, the following requirements could be placed upon the converter (i.e. layer-substrate system):
as good as possible adhesion of the film to thin sheets (substrate) of a neutron transparent material such as aluminum or an aluminum alloy,
a high transmission of the substrate for thermal and cold neutrons,
a good stability of the system with respect to radiation load and under mechanical and thermal stress.

The coatings should additionally have a high homogeneity in layer thickness, chemical composition and isotope ratio and as few impurities as possible. A high quantum efficiency of the converter layers for the neutron detection upon irradiation at small angles relative to the surface is a further aim of the invention. In general the 10B-containing coatings for solid detectors should be producible at favorable costs.

U.S. Pat. No. 6,771,730 discloses a semiconductor neutron converter with a boron carbide layer which contains the isotope 10B. The boron carbide was produced through plasma enhanced chemical vapor deposition (PECVD) on a silicon semiconductor layer.

WO 2013/002697 A1 describes a method for producing a neutron converter component which comprises a boron carbide layer. In this method the boron carbide is applied to a neutron transparent substrate, likewise by means of PECVD.

The known coatings do not, however, fulfill all the points of the abovementioned quality or economic requirements, in particular if large sheets are to be coated.

For example, in C. Höglund et al. J. Appl. Phys. 111, 104908 (2012), an improved adhesion is realized by temperature treatment and coating at a high rate. For the improved adhesion, greater layer thickness variation and higher production costs must be taken into account.

### SUMMARY OF THE INVENTION

It is the object of the present invention to provide a method for producing neutron converters which fulfills the above-described requirements for the converter (film+substrate): In particular, the requirement to have a continuous, homogeneous coating of a 10B-containing material in the range of a few micrometers and to possess very good adhesion and outstanding thermal and mechanical stability during long periods of irradiation.

Furthermore it is the object of the invention to provide a neutron converter with these improved properties. This has been realized by a 10B solid neutron converter consisting of a base (a substrate) and a 10B-containing film being successfully tested in a prototype detector.

These objects are achieved by a method according to the claims and a neutron converter according to the claims.

### DETAILED DESCRIPTION

According to the invention a metal substrate is polished in a first step and coated in a further step by means of sputtering with boron carbide or a boron film.

The fine grinding preferably takes place using grinding papers but can also be carried out using a polishing paste—an emulsion of metal dust, grinding liquid and grinding paper grains. During grinding, the upper material layers are removed using sandpaper grains (SiC, Al₂O₃, diamond or CBN). The grain or grade of the grinding paper or grinding paste used is preferably in the range of from 800 to 2500, wherein the term “polishing” is used in the case of finer grains or grades. The metallographic polishing process is based, like grinding, on the cutting removal effect of the polishing media, but the abrasion is somewhat lower than the case with grinding, as very fine grains are used.

The metal substrate is preferably initially finely grinded in successive steps using grinding papers and/or grinding pastes with increasingly fine grain and then polished.

SiC or Al₂O₃ papers or pastes are preferably used for fine grinding.

When using a grinding paper the fine grinding preferably takes place also using a grinding liquid as wet grinding. The grinding liquid is preferably selected from the group consisting of acetone, an alcohol such as methanol, ethanol, propanol or butanol, and water. Ethanol or water is preferably used as a grinding liquid. Even when using a polishing paste, the grinding liquid is preferably selected from the group consisting of acetone, an alcohol such as methanol, ethanol, propanol or butanol, and water.

The metal substrate is neutron transparent and is preferably selected from the group consisting of aluminum or an aluminum alloy such as a titanium-aluminum alloy.

After the fine grinding the metal substrate is preferably rinsed. Subsequently the polished and possibly rinsed metal substrate can be coated with an adhesion promoting layer such as a titanium layer. The adhesion promoting layer is preferably produced by sputtering. However, the pre-treatment achieves an adhesion between the converter layer and metal substrate which renders an adhesion promoting layer unnecessary in most cases.

Finally, the metal substrate is coated by means of sputtering with boron carbide or with boron film. B4C enriched with 10B is preferably used as boron carbide. The coating can be carried out with or without an adhesion promoter such as titanium. The layer thickness of the coating is preferably in the range of from 100 nm to 10 μm, more preferably 250 nm to 5 μm, most preferably 500 nm to 3 μm.

The sputtering both of the adhesion promoting layer and also of the converter layer is preferably carried out with solid magnetron sputtering sources, wherein the substrates are moved relative to the cathodes in order to produce a large-area homogeneous coating. The particle flow is preferably horizontally orientated in order to minimize contamination on the substrate and the sputter target. The coating rates are preferably in the range of from 0.1 to 1.0 nm/s. The coating preferably takes place under an argon pressure which can be as low as 1 μbar. Further details concerning coatings and methods, in particular magnetron sputtering, can be found in Milton Ohring, Materials Science of Thin Films, Academic Press, London 1992, to which reference is made here in full.

By applying the method according to the invention neutron converters can be produced with an even coating area of up to several square meters, such as in the range of from 1 to 100 m2. The layers produced in trials on metal substrates with a coating area of from 0.5 to 1.0 m2 were characterized by means of a specially developed test detector. High quantum efficiencies could be detected.

The coatings obtained have a high homogeneity in layer thickness, chemical composition and isotope ratio as well as a low level of impurities such as oxygen or nitrogen. Surprisingly, the coatings produced according to the invention have a good adhesion to thin sheets of aluminum or an aluminum alloy, even with large-area or thick coatings of up to 5 μm.

1. A method for producing neutron converts, wherein a neutron transparent metal substrate of aluminium or an aluminium alloy is polished in a first step by fine grinding and coated in a second step by sputtering with boron carbide.

2. The method according to claim 1, characterised in that the fine grinding takes place using grinding papers.

3. The method according to claim 2, characterised in that grinding papers of a grain in the range of from 1000-2500 are used.

4. The method according to claim 2, characterised in that the fine grinding additionally takes place using a grinding liquid.

5. The method according to claim 4, characterised in that the grinding liquid is selected from the group consisting of acetone, an alcohol and water.

6. The method according to claim 5, characterised in that ethanol is used as alcohol.

7. The method according to claim 1, characterised in that the neutron transparent metal substrate consists of aluminium or a titanium-aluminium alloy.

8. (canceled)

9. The method according to claim 1, characterised in that B₄C enriched with ¹⁰B is used as boron carbide for coating.

10. The method according to claim 8, characterised in that the boron carbide has 95% ¹⁰B.

11. (canceled)

12. (canceled)
